(19) United States
(12) Patent Application Publication
(10) Pub. No.: US 2018/0247842 A1
(43) Pub. Date: Aug. 30, 2018

(54) APPARATUS FOR THERMAL TREATMENT OF A SUBSTRATE, CARRIER AND SUBSTRATE SUPPORT ELEMENT

(71) Applicant: Heraeus Noblelight GmbH

(72) Inventors: Thomas PIELA, Hanau (DE); Larisa VON RIEWEL, Bergisch-Gladbach (DE)

(73) Assignees: Heraeus Noblelight GmbH, Hanau (DE); Heraeus Noblelight GmbH, Hanau (DE)

(21) Appl. No.: 15/556,382

(22) PCT Filed: May 19, 2017
(86) PCT No.: PCT/EP2017/062095

§ 371 Date: Sep. 7, 2017

(30) Foreign Application Priority Data
Jun. 20, 2016 (DE) 102016111234.8

(51) Int. Cl. H01L 21/67; H01L 21/673; H05B 1/02; H05B 3/24

(52) U.S. Cl. CPC H01L 21/67103; H01L 21/67306; H05B 3/24; H05B 1/0233; H01L 21/67323

(57) ABSTRACT

An apparatus for thermal treatment of a substrate is provided. The apparatus has a heating device and a carrier provided with a support surface for the substrate. The apparatus permits a high substrate throughput. At least part of the carrier contains a composite material containing an amorphous matrix component and an additional component containing a semiconductor material, and a conductor path that is part of the heating device and made of an electrically conducting resistance material that generates heat when current passes through it is applied to a surface of the composite material.

### CROSS-REFERENCE TO RELATED APPLICATIONS

This application is a Section 371 of International Application No. PCT/EP2017/062095, filed May 19, 2017, which has not yet been published, and the disclosure of which is incorporated herein by reference.

### BACKGROUND OF THE INVENTION

During the production and processing of silicon wafers, it is frequently necessary to subject the silicon wafers to a thermal treatment. Silicon wafers are thin, wafer-shaped substrates that have a substrate top side and a substrate bottom side. For the thermal treatment of silicon wafers, apparatuses that are used have a heating device, generally in the form of one or a plurality of infrared emitters, in addition to a substrate receiving element.

Since thermal treatment of silicon wafers frequently occurs under special conditions, for instance in a vacuum or in another, suitable atmosphere such as a reactive atmosphere, the substrate receiving element is generally located in a gas-tight closed process chamber. High throughput of the wafers is achieved during the thermal processing when a plurality of wafers is subjected to the thermal treatment in the process chamber at the same time. To this end, the wafers are advantageously held on a carrier that, loaded with the plurality of wafers, is supplied to thermal treatment.

Such carriers frequently have vertical structures; they essentially comprise an upper and a lower limiting plate that are joined to one another by a plurality of slotted transverse bars. During the technical processing of wafers for semiconductors, these carriers are used, for example, in a furnace, in a coating or etching system, but also for transporting and storing wafers. Such a carrier is known, for example from DE 20 2005 001 721 U1. Alternatively and in addition, horizontal structures are used in which the wafers are arranged in a plurality of levels like a shelving system.

However, a disadvantage of known carriers is that only a little assembly space remains between the wafers held in the carrier, which leads to the heating device being arranged at the side of the carrier. Irradiation of the wafers from the side is generally linked to uneven radiation of the edge and center regions of the wafers. This may lead to longer processing times since the irradiation must continue until even the center region of the wafer has reached the selected temperature.

In known apparatuses, the infrared emitters are arranged in the process chamber in order to permit the highest possible irradiation intensity on the wafer surface. A good, uniform thermal treatment of substrates with large surface areas is attained when a plurality of infrared emitters are located in the process chamber. The infrared emitters are generally arranged with the longitudinal axes of their emitter tubes parallel to one another. The infrared emitters are preferably located at the top and bottom sides of the substrate. However, this requires the presence of a comparatively large available assembly space above and/or below the wafer that is to be irradiated.

The electrical contacting of the infrared emitter is generally outside of the process chamber. This has the advantage that electrical discharges at the contacting sites are avoided inside the process chamber. However, in this case, the infrared emitters must be conducted through the process chamber wall so that a special seal is required for the feedthroughs.

From DE 10 2008 063 677 B4, for instance, an infrared emitter is known that may be installed in a vacuum chamber and that for gas-tight sealing is provided with a sealing element in the form of an O-ring. Such seals have the disadvantage, however, that the sealing element is regularly subjected to high thermal stresses that can damage the sealing element. It is therefore complicated to attain a continuous thermal seal of feedthroughs for the infrared emitter.

Finally, the infrared emitters arranged into the process chamber have a certain spatial extension and require the availability of a certain amount of assembly space. The assembly space of apparatuses that are used for thermal treatment of substrates is frequently limited and cannot be enlarged as desired. Moreover, additionally required assembly space may contribute to an increase in the required processing times, since the evacuation process is longer in apparatuses having larger dimensions, for example. This may result in the throughput being reduced during the thermal treatment of the wafers.

The underlying technical object of the invention is therefore to provide an apparatus that permits high substrate throughput.

Moreover, the underlying object of the invention is to provide a carrier and a substrate support element for a carrier that permits simple thermal treatment of substrates with a high throughput.

### BRIEF SUMMARY OF THE INVENTION

The present invention thus relates to an apparatus for thermal treatment of a substrate; the apparatus has a heating device and a carrier provided with a support surface for carrying the substrate.

The present invention furthermore relates to a carrier for thermal treatment of a substrate, having at least one support surface for a substrate.

Finally, the present invention relates to a substrate support element for a carrier for thermal treatment of a substrate, having a support surface for the substrate.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

FIG. 1 depicts an exemplary embodiment of a carrier for thermal treatment of a substrate according to an embodiment of the invention; this carrier is designed for receiving semiconductor wafers in a horizontal orientation;

FIG. 2 is a sectional depiction of an embodiment of an irradiation apparatus for thermal treatment of a substrate according to the invention, in which the electrical contacting of the conductor path is accomplished via a single current feedthrough into the process chamber;

FIGS. 3A and 3B provide perspective views of the top and bottom side of a first embodiment of a substrate support element for a carrier for thermal treatment of a substrate according to the invention;

FIG. 4 is a top view of a second embodiment of a substrate support element for a carrier for thermal treatment of a substrate;

FIG. 5 is a top view of the bottom side of a third embodiment of a substrate support element according to the invention to which two individually electrically controllable conductor paths have been applied; and,

FIG. 6 is a top view of the bottom side of a fourth embodiment of a substrate support element according to the invention to which two individually electrically controllable conductor paths have been applied.

### DETAILED DESCRIPTION OF THE INVENTION

Apparatuses in the context of the invention are employed, for instance, for thermal treatment of semiconductor wafers in the semiconductor and photovoltaic industries; they are generally designed for simultaneous irradiation of a plurality of substrates and as a rule are used in non-continuous processes (batch processes). In these apparatuses, the substrate is normally arranged in a closed process chamber that is designed for thermal treatment with particular environmental conditions; the process chamber may preferably be evacuated or may be pressurized with a reactive or protective gas.

Carriers in the context of the invention are designed to receive and hold one or a plurality of substrates and/or may be used for transporting the latter; these carriers have one or a plurality of support surfaces, each of which may be designed for receiving one or a plurality of substrates. The carriers may be embodied in one piece or in multiple pieces. In the latter case, the carrier frequently has a holding frame in which one or a plurality of substrate support elements may be received.

Substrate support elements in the context of the invention have at least one support surface for carrying a substrate, for instance in the form of a depression. They are used, for instance, as holders or carriers for one or a plurality of substrates.

With respect to the apparatus for thermal treatment of a substrate, the aforesaid object, starting from the aforementioned apparatus, is achieved according to the invention in that at least part of the carrier is produced from a composite material comprising an amorphous matrix component and an additional component in form of a semiconductor material, wherein a conductor path that is part of the heating device and that is made of an electrically conducting resistance material that generates heat when current passes through it is applied to the surface of the carrier.

Known apparatus for thermal treatment of a substrate have a carrier and a heating device. In these apparatus, the carrier and the heating device are embodied as separate assemblies, wherein the heating device is generally arranged in the process chamber adjacent to the carrier, for instance above and/or below the carrier, or the heating device is located at a side of the carrier. The heating device comprises a thermal radiation emitting heating element as well as the electrical connections and circuits required for operating the heating element.

The underlying idea of the present invention is that a high substrate throughput may be attained if the apparatus has the most compact possible design. According to the invention, this is attained in that no separate heating device is used and the heating device is integrated into the carrier. Moreover, a carrier having an integrated heating device contributes to very uniform irradiation of a substrate placed thereon.

According to the invention, therefore, two modifications of the carrier are suggested, one relating to the material of the carrier and the other relating to the type of electrical contacting of the carrier.

To permit emission of infrared radiation by the carrier, at least part of the carrier is produced from a composite material. The composition of the composite material is selected such that a thermally excitable material is obtained that can assume a low-energy starting state and can assume a high-energy excited state. If such a material returns from the excited state to the starting state, energy is released, preferably in form of infrared radiation, and is available for radiating the substrate.

The energy required for exciting the composite material is provided by a conductor path made from an electrically conducting resistance material that is applied to a surface of the carrier, the conductor path generates heat when current is flowing there through. The conductor path acts as a “local” heating element with which at least a portion of the carrier may be locally heated. However, the conductor path does not form the actual heating element with which the substrate is heated in the apparatus, but instead is primarily for heating another apparatus component, specifically the carrier itself. The conductor path is dimensioned such that it heats a part of the carrier that is made of composite material. The transport of heat from the electrical resistance element to the carrier may be based on thermal conduction, convection, or thermal radiation.

Moreover, a heating device integrated into the carrier contributes to minimizing the average distance from the heating element to the substrate surface. This permits a particularly effective heating up process and short processing times.

In an apparatus having such a carrier structure, the part of the carrier that is produced from the composite material forms the actual element that emits infrared radiation. The composite material includes the following components.

The amorphous matrix component represents the largest portion of the composite material in terms of weight and volume. It determines, to the greatest extent, the mechanical and chemical properties of the composite material, for example, its temperature resistance, strength, and corrosion properties. Since the matrix component is amorphous it preferably comprises glass the geometric configuration of the carrier may be adapted more simply to the requirements of the specific use of the inventive apparatus than a carrier made of crystalline materials. Furthermore, a composite material that essentially comprises an amorphous material component is easy to adapt to special substrate shapes.

The matrix component may comprise undoped or doped silica glass and, besides SiO₂, may include other oxide, nitride, or carbide components in a quantity up to a maximum of 10 wt. %.

Moreover, according to the invention it is also provided that an additional component in the form of a semiconductor material is intercalated in the matrix component. The additional component forms a discrete amorphous phase dispersed in the amorphous matrix component or forms a crystalline phase.

A semiconductor has a valence band and a conduction band that may be separated from one another by a forbidden zone having a width of up to ΔE≈3 eV. The width of the forbidden zone is for instance 0.72 eV for Ge, 1.12 eV for Si, 0.26 eV for InSb, 0.8 eV for GaSb, 1.6 eV for AlSb, 2.5 eV for CdS. The conductivity of a semiconductor depends on how many electrons cross the forbidden zone and can travel out of the valence band into the conduction band. In principle, at room temperature only a few electrons can cross the forbidden zone and travel into the conduction band, so that as a rule at room temperature a semiconductor has only limited conductivity. However, the level of conductivity of a semiconductor is substantially dependent on the latter's temperature. If the temperature of the semiconductor material rises, the probability that there is enough energy available to move an electron from the valence band to the conduction band increases as well. Therefore, semiconductor conductivity increases with temperature. At the right temperatures, semiconductor materials have good electrical conductivity.

The additional component as a discrete phase is distributed uniformly or intentionally non-uniformly. The additional component determines to a large extent the optical and thermal properties of the substrate. More precisely, in the infrared spectrum, that is, in the wavelength range between 780 nm and 1 mm, it causes absorption. For at least some of the radiation in this spectrum range, the additional component has an absorption that is higher than that of the matrix component.

The phase regions of the additional component act in the matrix as optical discontinuities and result, for example, in that the composite material may visually appear black or blackish-gray at room temperature, depending on layer thickness. In addition, the discontinuities themselves are heat absorbing.

The additional component is preferably present in the composite material in a manner and quantity such that in the composite material it causes a spectral emittance 6 of at least 0.6 for wavelengths between 2 μm and 8 μm at a temperature of 600° C.

A particularly high emittance may be attained when the additional component is present as an additional component phase and has a non-spherical morphology with maximum dimensions of on average less than 20 μm but preferably more than 3 μm.

The non-spherical morphology of the additional component phase also contributes to high mechanical strength and to a low tendency of the composite material to form cracks. The term “maximum dimension” refers to the longest extension of an insulated region with additional component phase detectible in a micrograph. The aforesaid average is found from the mean value of all of the longest extensions in a micrograph.

According to Kirchhoff s Radiation Law, spectral absorptivity α_{λ} and spectral emittance ε_{λ} of a real body in thermal equilibrium are equal.

α_{λ}=ε_{λ} (1)

The additional component thus means that the substrate material emits infrared radiation. The spectral emissivity ε_{λ} may be calculated as follows with known targeted hemispherical spectral reflectance R_{gh} and transmittance T_{gh}:

ε_{λ}=1−R_{gh}−T_{gh} (2)

“Spectral emissivity” shall be construed to mean “spectral normal emissivity.” It is found using the measuring principle known as “Black-Body Boundary Conditions” (BBC) and published in “Determining The Transmittance And Emittance Of Transparent And Semitransparent Materials At Elevated Temperatures,” J. Manara, M. Keller, D. Kraus, M. Arduini-Schuster; 5th European Thermal-Sciences Conference, The Netherlands (2008).

The amorphous matrix component in the composite material, that is, in connection with the additional component, has higher thermal radiation absorption than would be the case without the additional component. This results in improved thermal conduction from the conductor path into the substrate, more rapid distribution of the heat, and a higher rate of radiation onto the substrate. Because of this it is possible to provide greater radiant power per unit of surface area and also to produce a uniform emission and uniform temperature field, even with thin support structure wall thicknesses and/or with a comparatively low conductor load density. A carrier having a thin wall thickness has a low thermal mass and permits rapid temperature change. A cooling element is therefore not necessary.

In a preferred embodiment of the apparatus according to the invention, the additional component is present in a type and quantity that causes a spectral emissivity 6 of at least 0.75 for wavelengths between 2 μm and 8 μm in the composition material at a temperature of 1000° C.

Consequently, the composite material has a high absorption and emission capacity for thermal radiation between 2 μm and 8 μm, that is, in the wavelength range of the infrared radiation. This reduces the reflection on the composite material surfaces so that, assuming negligibly small transmission, the result is reflectance of a maximum of 0.25 for wavelengths between 2 μm and 8 μm and at temperatures greater than 1000° C. and of 0.4 at temperatures of 600° C. Non-reproducible heating by reflected thermal radiation is thus avoided, which contributes to a uniform or desired non-uniform temperature distribution.

In a preferred embodiment of the apparatus according to the invention, it is provided that the apparatus has a process chamber in which the carrier is located, said process chamber has a process chamber wall with a current feedthrough through which a first electrical potential and a second electrical potential is conducted into the process chamber for electrically contacting the conductor path.

An electrical supply for the conductor path is required for operating the heating device that is integrated in the carrier. Since only a small operating current is required for operating the conductor path, compared to a conventional heating device, the conductor path may be electrically contacted via a single current feedthrough into the processing space. Current feedthroughs of any type have the disadvantage that they must be sealed. However, such seals are frequently problematic, especially because a permanent seal is nearly impossible to achieve. The limiting factor is frequently the standing time of the light elements used, specifically when they are exposed to high radiant power or reactive atmospheres. One advantage of the apparatus according to invention is that even a plurality of conductor paths of a carrier may be supplied by means of one current feedthrough, so that only two electrical potentials have to be conducted into the process chamber. Preferably only a first individual line having the first electrical potential and a second individual line having the second electrical potential are conducted into the process chamber. The first individual line and the second individual line may be integrated into a shared cable. The conductors connected thereto may be switched in parallel or in series.

With respect to the carrier for thermal treatment of a substrate, the aforesaid object, starting from a carrier cited in the foregoing, is achieved according to the invention in that at least part of the carrier is produced from a composite material comprising an amorphous matrix component and an additional component in the form of a semiconductor material, and a conductor path made of an electrically conducting resistance material that generates heat when current flows through it is applied to a surface of the composite material.

The inventive carrier is in particular designed for thermal treatment of a semiconductor wafer (silicon wafer).

Known carriers for thermal treatment of a substrate are normally produced from a temperature-resistant material. Moreover, especially in semiconductor production, the yield and the electrical operating performance of semiconductor components depends to a very large extent on the success to prevent the semiconductor from being contaminated with impurities during production. To prevent contamination from being introduced into the process chamber through the carrier, known carriers are frequently produced from a single material having a high chemical resistance so that this represents a low contamination risk for the substrate.

The carrier according to the invention may be embodied in one piece or in multiple pieces; it may in particular have a vertical structure or a horizontal structure. The carrier preferably has a horizontal structure. In horizontal structures, the support surface for the substrate runs parallel to the surface of the floor of a process chamber. If a plurality of carrier elements is provided, they are arranged parallel to one another. Such a horizontal orientation of the substrates has the advantage that the substrates are positioned on its respective support surface due to gravity. This permits good heat transfer from the support surface to the associated substrate. In this context, the use of a shelving-type carrier structure has proved particularly advantageous, since with this type of carrier the energy required for heating the substrate may be provided via two mechanisms, specifically by direct irradiation of the substrate and also indirectly by thermal conduction with the carrier itself.

Since the carrier according to the invention is produced from a composite material and at the same time is provided with a conductor path made of a resistance material, infrared radiation may be produced directly with the carrier. The inventive carrier therefore has two functions: first, the carrier may be used for transporting and storing substrates, and second, the carrier may also be employed as a radiation source for thermal treatment of the substrates without an additional, external radiation source being required. It is also not necessary, for instance, to relocate substrates into a special carrier suitable for irradiating the substrates.

According to the invention, the material from which the carrier is produced and the type of electrical contacting are selected such that at least some of the carrier material may be converted, by means of energy introduced into the material, from a starting state to an excited state, specifically such that during its return from the excited state to the starting state the carrier material emits infrared radiation that is provided for irradiating the substrate.

In an apparatus having such a carrier, the part of the carrier that is produced from the composite material is the actual infrared-emitting element. The composite material includes an amorphous matrix component and an additional component in the form of a semiconductor material as have been described in detail in the foregoing with respect to the apparatus according to the invention.

Since a conductor path made of an electrically conducting resistance material is applied to a surface of the carrier, heat may be generated by the resistance material when current flows through it. The conductor path acts as a “local” heating element with which at least a sub-region of the support structure may be heated locally.

In one preferred embodiment of the carrier according to the invention, it is provided that in the region of the support surface it is produced from the composite material.

As a rule, carriers that are used for thermal treatment of a substrate are produced from a material that is characterized to a large extent by good temperature stability and good chemical resistance. In semiconductor production, in particular, the yield and the electrical operating performance of semiconductor elements depend to a large extent on the success to prevent the semiconductor from being contaminated with impurities during semiconductor production. Such contamination may be caused, for example, by the apparatus used.

All or part of the carrier may be produced from the composite material. A carrier that is produced entirely from the composite material is simple and cost-effective to produce. The top of such a support surface may be completely or partially covered with the conductor path. It has proved advantageous when only part of the top of the carrier is covered with the conductor path. In this case, only the regions of the carrier that are associated with the conductor path are directly thermally excited. Regions that are not excited directly thermally do not show any appreciable infrared radiation emission below a temperature of 40° C. The radiation region may be adapted to the substrate shape by arranging the layout of the conductor path and selecting the region covered with the conductor path appropriately, so that a uniform thermal treatment of the substrate results.

To ensure uniform irradiation of a substrate placed onto the support surface, it has proved advantageous when the carrier is produced from the composite material only in the region of the support surface or when the conductor path is applied to the carrier such that the latter is excited only in the region of the support surface. In both cases, only the support surface acts as an emitter of infrared radiation. The shape of the support surface may simply be adapted to the shape of the substrate. In this case, a heating device having the same shape is allocated to a substrate placed onto the support surface, so that particularly uniform irradiation of the substrate is made possible.

The support surface is preferably embodied as a flat surface.

Producing a flat surface is not very complex; a particularly high quality of the support surface may be attained, for instance, by smoothing. A flat support surface furthermore has the advantage that a substrate that is likewise flat has the largest possible contact surface with the support surface. This contributes to particularly uniform heat transfer to the substrate.

A substrate applied onto the support surface may be beared on the support surface completely or in part. Preferably the entire side of a substrate applied onto the support surface is facing against the support surface. This has the advantage that the temperature of the side positioned thereon may be adjusted to the greatest extent possible by electrically actuating the conductor path of the support surface so that the most uniform possible heating of the substrate is permitted.

The support surface for the substrate is preferably in the range of 10,000 mm² to 160,000 mm² in size, particularly preferably in the range of 10,000 mm² to 15,000 mm² in size.

A support surface in the range of 10,000 mm² to 160,000 mm² is large enough to receive current substrates, for instance of semiconductor wafers. In addition, a support surface of more than 160,000 mm² is complicated to produce.

It has proved advantageous when the area size of the support surface is in the range of 10,000 mm² to 15,000 mm². A support surface in this range is in particular suitable for receiving wafers as they are used in the manufacture of electronic components, for instance in the manufacture of integrated circuits. It has proved advantageous when the support surface has a square or round shape. In the case of a square shaped support surface, its size is preferably between 100 mm×100 mm and 122 mm×122 mm; for a round shaped support surface, the support surface diameter is preferably between 56 mm and 120 mm.

It has proved advantageous when the amorphous matrix component is silica glass, the semiconductor material is present in elementary form, wherein the proportion by weight of the semiconductor material is in the range between 0.1% to 5%.

In this context, it has proved advantageous when the amorphous matrix component and the additional component have electrically insulating properties at temperatures below 600° C.

Silica glass is an electrical insulator and, in addition to having high strength, it has good resistance to corrosion, to temperature, and to thermal shock; moreover, it is available in high purity. Therefore it is also suitable as a matrix material for high-temperature heating processes at temperatures up to 1100° C. No cooling is necessary.

In the matrix, the fine regions of a semiconductor phase act, on the one hand, as optical discontinuities, and, depending on layer thickness, may result in the substrate material visually appearing black or blackish-gray at room temperature. On the other hand, the discontinuities also have effects on the heat absorption of the composite material overall. This may essentially be traced to the properties of the finely distributed elementary phases from the semiconductor, according to which, firstly, the energy between valence band and conduction band (band gap energy) decreases with the temperature, and, secondly, when the activation energy is high enough, electrons cross from the valence band into the conduction band, which is associated with a significant increase in the absorption coefficient. The thermally activated occupation of the conduction band may result in that the semiconductor material can be transparent to some extent at certain wavelengths (such as about 1000 nm or more) at room temperature and can be opaque at high temperatures.

As the temperature of the composite material increases, therefore, absorption and emissivity can therefore increase sharply. This effect is a function, inter alia, of the structure (amorphous/crystalline) and of doping of the semiconductor.

The additional component is preferably elementary silicon. Pure silicon, for example, shows a marked increase in emission starting at about 600° C., but this reaches saturation starting at about 1000° C.

The semiconductor material, and, in particular, the preferably used elementary silicon therefore cause a black coloration of the glassy matrix component, specifically at room temperature, but also at elevated temperatures, for example above 600° C. This attains good emission characteristics in the context of a broad-band, high emission at high temperatures. The semiconductor material, preferably the elementary silicon, forms a discrete Si phase dispersed in the matrix. It may include a plurality of semimetals or metals (metals, however, at a maximum of up to 50 wt. %, but preferably no more than 20 wt. %, relative to the weight portion of the additional component). The composite material does not show any open porosity, but at best has a closed porosity of less than 0.5% and a specific density of at least 2.19 g/cm³. It is therefore suitable for carriers in which the primary issue is the purity or gas-tightness of the material from which the carrier is produced.

The heat absorption of the composite material depends on the proportion of the additional component. The weight portion of the additional component should therefore preferably be at least 0.1%. On the other hand, a high volume portion on the part of the additional component may have a negative effect on the chemical and mechanical properties of the matrix. Given this, the weight portion of the additional component is preferably in the range between 0.1% and 5%

One embodiment of the carrier in which the amorphous matrix component is silica glass and preferably has a chemical purity of at least 99.99% SiO₂ and a cristobalite content of at most 1% has proved particularly advantageous for reducing a risk of substrate contamination from the carrier. Because the matrix has a low cristobalite content of 1% or less, there is a low tendency for devitrification and thus a low risk of crack formation during use as a carrier. By this high demands on freedom from particles, on purity, and on inertness, as generally exist for semiconductor production processes, are also satisfied.

It has proved advantageous when the conductor path is produced from platinum, high heat resistant steel, tantalum, a ferritic FeCrAl alloy, an austenitic CrFeNi alloy, or from a molybdenum-base alloy and has a cross-sectional area in the range of 0.01 mm² to 2.5 mm².

The conductor path is a part of the heating device with which the carrier is heated; it is produced from a resistance material that generates heat when current flows through it. The resistance material forms an electrical component with which electrical energy may be converted to thermal energy (heat); it may therefore also be called a thermal resistor. The thermal output of the resistance material depends on the specific resistance of the material, the cross-section and length of the material, and on the operating current or operating voltage applied thereto.

Since operating current and operating voltage cannot be increased in a manner as desired, because otherwise the resistance material can melt, the thermal output may be adapted simply and rapidly by varying the length and cross-section of the resistance material. In this context, it has proved advantageous when the cross-sectional area is in the range of 0.01 mm² to 2.5 mm². Only limited currents (of less than 1 A) can flow through a conductor path having a sectional area of less than 0.01 mm². A conductor path having a cross-sectional area of more than 2.5 mm² represents a high resistance and requires high operating currents (greater than 8 A). Moreover, such a conductor path is associated with a high turn-on current of greater than 128 A, so that a turn-on current limiter would be required.

It has proved particularly advantageous when the cross-sectional area is in the range of 0.01 mm² to 0.05 mm². A cross-sectional area in this range is distinguished by a particularly advantageous voltage/current ratio; it permits in particular operation with voltages in the range of 100 V to 400 V with currents from 1 A to 4.5 A.

It is possible to vary the conductor length by making a suitable selection of the shape of the conductor path. With respect to a most uniform possible temperature distribution, it has proven advantageous when the conductor path is embodied as a line pattern that covers the surface of the substrate such that an interposing space of at least 1 mm, preferably at least 2 mm, remains between adjacent conductor path segments. A low coverage density is characterized in that the minimum distance between adjacent conductor path segments is 1 mm or more, preferably 2 mm or more. A large distance between conductor path segments prevents flashovers that can occur in particular when operating with high voltages under a vacuum. The apparatus and the carrier according to the invention are preferably designed for low voltages of less than 80 V and therefore are particularly suitable for operating in vacuum. The conductor path preferably runs in a spiral or meandering line pattern. This permits uniform coverage with a single conductor. A single conductor path may be connected to a current source and controlled in a particularly simple manner.

It has proved advantageous when contact elements are provided at the conductor path ends. Contact elements provide simplified electrical contacting for the conductor path; they preferably form a plug element of a plug connector. The plug connector is for detachably connecting the contact element to an electrical current supply. This permits simple separation and connection of the conductor with an electrical supply line and in particular with a current/voltage source.

The resistance material is preferably high heat-resistant steel, tantalum, a molybdenum base alloy, an austenitic CrFeNi alloy, or a ferritic FeCrAl alloy, for example Kanthal® (Kanthal® is a trademark of SANDVIK AB.).

The conductor path is particularly preferably produced from platinum because such a conductor is especially highly efficient with respect to converting electrical energy to thermal energy. Moreover, a conductor path made of platinum is simple and cost-effective to produce; it may be embodied as a fired thick-film layer. Such thick-film layers are produced, for instance, from resistance paste screen printing or from metal-containing ink by ink-jet printer and then are fired in at high temperature.

In the preferred embodiment of the inventive support structure, it is provided that the carrier comprises at least one support element having the support surface, and that has a top and a bottom side, wherein the support surface is allocated to the top side and the conductor path is allocated to the bottom side.

The carrier may comprise one or a plurality of support elements that may themselves have one or a plurality of support surfaces. A single substrate or a plurality of substrates may be placed onto the support surface. Since the support surface is allocated to the top side of the support element, the substrate may simply be placed thereon. The substrate is preferably placed onto the support surface such that as much of the surface of one side of the substrate as possible is positioned against the support surface. This permits particularly uniform heating of the substrate, especially using thermal conduction and thermal radiation.

Since the conductor path is allocated to the bottom side of the support element, the composite material of the support element can be heated and excited sufficiently, without the conductor path preventing the radiation of infrared radiation towards a substrate positioned on the top of the support element. On the other side, between adjacent conductor path segments, the bottom side of the carrier has intermediate spaces via which the infrared radiation may be emitted. If two support elements are arranged above one another, the radiation emitted from the bottom side of the upper support element may be used for irradiating a substrate positioned on the top of the lower support element.

One particularly advantageous embodiment of the carrier is characterized in that the composite material has a surface facing the conductor path, in that a part of this surface is covered with a cover layer made of porous silica glass, wherein at least part of the conductor path is embedded in the cover layer.

The cover layer made of opaque silica glass acts as a diffuse reflector and protects and simultaneously stabilizes the conductor path. Using the cover layer, it is possible to deflect the radiation that is emitted in the direction of the bottom side of the support element onto the substrate positioned on the top of the support element. In this way, the radiation emitted by a support element is available for irradiating the substrate positioned thereon. Since the cover layer acts as a diffuse reflector, uniform irradiation of the substrate is made possible.

The manufacture of such a cover layer from opaque silica glass is described, for instance, in WO 2006/021416 A1. It is produced from a dispersion that includes amorphous SiO₂ particles in a liquid. It is applied to the surface of the support element facing the conductor path, preferably the bottom side of the support element, and dried to create a green sheet; the latter is sintered at high temperature. Sintering of the green sheet and firing of the conductor path is preferably done in one and the same heating process.

It has proved particularly advantageous when a plurality of conductor paths are provided, each of said conductor paths being individually electrically controllable.

The provision of a plurality of conductor paths permits individual adaptation of the irradiation power attainable with the carrier. On the one hand, the radiant power of the composite material may be adjusted by appropriately selecting the distances between adjacent conductor path segments. Segments of the composite material are heated with different intensities so that they emit infrared radiation with different radiant power.

Alternatively, conductor paths may be individually actuated electrically so that they are operated with different operating voltages or operating currents. It has been demonstrated that in particular the edge regions of a substrate are frequently more intensively heated than the center region of the substrate. The reason for this is that the edge region is more easily accessible to infrared radiation and, as a rule, is more intensively irradiated when the top of the substrate is smaller than the support surface. Varying the operating voltages or currents applied to the specific conductor paths permits a simple and rapid adaptation of the temperature distribution on the substrate to be heated.

The carrier according to the invention is preferably designed for receiving a wafer-shaped substrate made of semiconductor material in a horizontal orientation; it is preferably embodied like a type of shelving and is used for thermal treatment of a semiconductor wafer.

With respect to the substrate support element, the object cited above is attained, starting from the aforementioned substrate support element in that the support element is produced from a composite material that comprises an amorphous matrix component as well as an additional component in the form of a semiconductor material, wherein a conductor path that is made of an electrically conducting resistance material that generates heat when current passes through it is applied to a surface of the composite material.

Carriers that are used for thermal treatment of a substrate frequently have multiple parts. They may have a holding frame into which a plurality of substrate support elements, for instance, may be placed. Alternatively, a plurality of substrate support elements may also be stacked on top of one another. This has the advantage that the size of the support structure may be adapted individually to the specific irradiation process. Each substrate support element is preferably designed for receiving a single substrate.

The substrate support element may be produced entirely or in part from the composite material. As already explained in greater detail in the foregoing regarding the carrier, the substrate support element is produced from a special material that may be caused by means of a conductor made of a resistance element to go from a starting state to an excited state, wherein the material emits radiation in the form of infrared radiation. Reference is made to the information provided above about the apparatus and about the carrier concerning the chemical composition of the composite material made of matrix component and additional component.

The substrate support element according to the invention may advantageously be placed in a known carrier for thermal treatment of a semiconductor wafer. Advantageously the carrier according to the invention comprises a plurality of substrate support elements, wherein the latter are arranged such that their respective substrate support surfaces run parallel to one another.

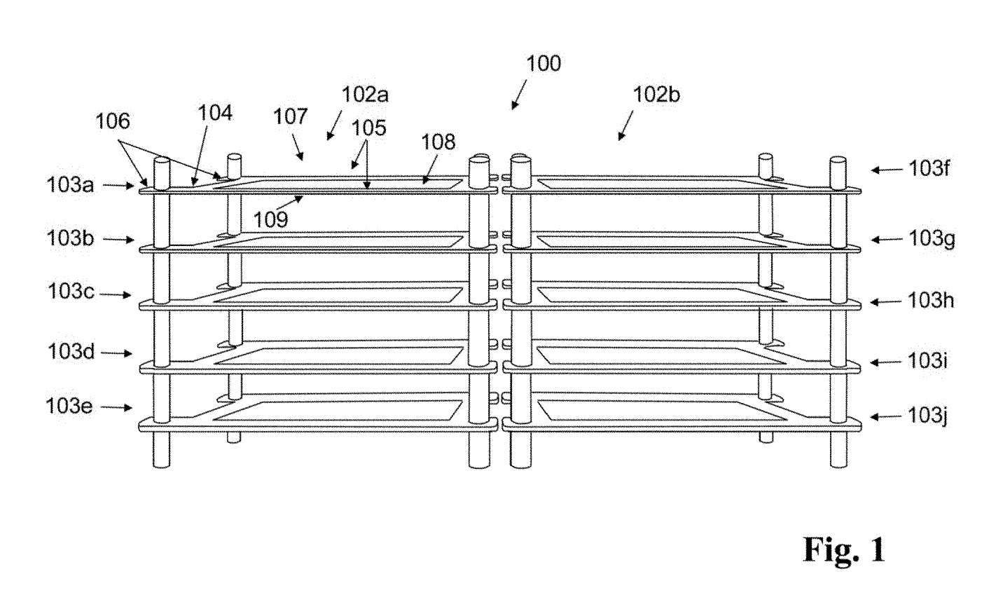

FIG. 1 is a perspective view of an embodiment of a carrier according to the invention, which overall has the reference number 100. The carrier 100 is designed for thermal treatment of silicon wafers and is employed, for example, in the semiconductor and photovoltaic industries. Carriers of this type are also known in English as “stacks”.

The carrier 100 has a shelving-like construction that is designed for receiving silicon wafers in a horizontal orientation. The carrier 100 depicted as an example in FIG. 1 comprises two receiving frames 102a, 102b, each of which has five levels 103a-e and 103f-j for receiving one silicon wafer per level. The total receiving capacity of the carrier 100 is ten silicon wafers. In principle, the carrier 100 and the receiving frames 102a, 102b may be dimensioned such that a desired number of wafers may be accommodated.

In the carrier 100, the receiving frames 102a, 102b are each embodied in a single piece. The carrier is produced completely from a composite material that comprises an amorphous matrix component and an additional component.

The amorphous matrix component is a matrix of silica glass having a chemical purity of 99.99%; the cristobalite content of the amorphous matrix component is 0.25%.

In this matrix, a phase made of elementary silicon in the shape of non-spherical regions is evenly distributed. The additional component has a proportion by weight of 2% (m/m). The maximum dimensions of the Si phase regions are on average (median value) in the range of about 1 μm to 10 μm.

The composite material is gas-tight; it has a density of 2.19 g/cm³ and is stable in air up to a temperature of about 1,150° C.

The carrier 100 appears visually translucent to transparent. When viewed under the microscope, it has no open pores and any closed pores have maximum dimensions of on average less than 10 μm. The intercalated Si phase contributes to the opacity of the composite material, on the one hand, and has effects on the optical and thermal properties of the composite material. At high temperatures, the composite material exhibits high absorption of thermal radiation and high emissivity.

In one alternative embodiment (not shown), the entire carrier is embodied in one piece. In another alternative embodiment of the carrier 100 (also not shown), it is formed from a plurality of substrate support elements. The substrate support elements may either be stacked on one another or a holding frame in which the substrate support elements are received may be provided. This has the advantage that size and receiving capacity may be selected as desired, for example by suitably selecting the holder frame size or the number of substrate support elements stacked on one another.

The levels 103a-e and 103f-j are embodied identically; therefore the level 103a is described in greater detail in the following as an example representing the levels 103 b-e and 103f-j: The level 103a has a length of 200 mm (corresponding to the longitudinal side 105 including the projections 106 having a projection length of 30 mm). The width of the level 103a is 150 mm (corresponding to the transverse side 104). The thickness of the level 103a is 2 mm.

The level 103a has a top 107 and a bottom 109 opposing the top 107. The top 107 is provided with a depression that acts as a support surface 108 for a flat substrate. The support surface 108 has a rectangular shape and has a length of 101 mm and a width of 101 mm.

A conductor path (not shown) is produced on the bottom side 105 by applying and firing in a platinum resistance paste. The conductor path is only allocated to a portion of the bottom side 105; the conductor path extends across that part of the surface of the bottom side 109 that is directly opposite the support surface 108 and the surface area of which corresponds to the support surface 108. The conductor runs in a spiral-shaped line pattern. Clamps (not shown) that permit the conductor path to be electrically connected to a current supply (not shown) are provided at both ends of the conductor path.

If an electrical potential is applied to the conductor path, the conductor path heats up. At the same time, the carrier 100 is heated up in the region of the support surface 108. From a predetermined temperature, the emissivity of the support surface 108 increases significantly. This may certainly be reasoned by the fact that the phase made of elementary silicon that was added to the matrix is a semiconductor and by the fact that the energy between valence band and conduction band (band gap energy) of the semiconductor decreases with temperature. If the temperature and activation energy are high enough, electrons cross from the valence band to the conduction band so that when they return to the valence band, energy is released in the form of thermal radiation. The thermally activated occupation of the conduction band leads to the semiconductor material emitting thermal radiation in a certain scope for specific wavelengths at room temperature. This effect is amplified by high temperatures of the carriers, especially with carrier temperatures higher than 600° C. Since the conductor path is arranged opposite the support surface 108, the support surface 108 can act as a plate-like radiation surface for thermal radiation. Some of the emitted thermal radiation is also coupled into the carrier 100 so that the latter overall emits thermal radiation. Thermal radiation especially in the region of the support surface 108.

In order to be able to direct the emitted thermal radiation onto a substrate placed onto the support surface 108, for instance, a reflector layer (not shown) is also applied to the conductor path that is applied to the bottom side 105. The reflector layer comprises opaque silica glass and has a mean layer thickness of about 1.7 mm. It is characterized by a lack of cracks and a high density of about 2.15 g/cm³; it is heat resistant up to temperatures higher than 1100° C.

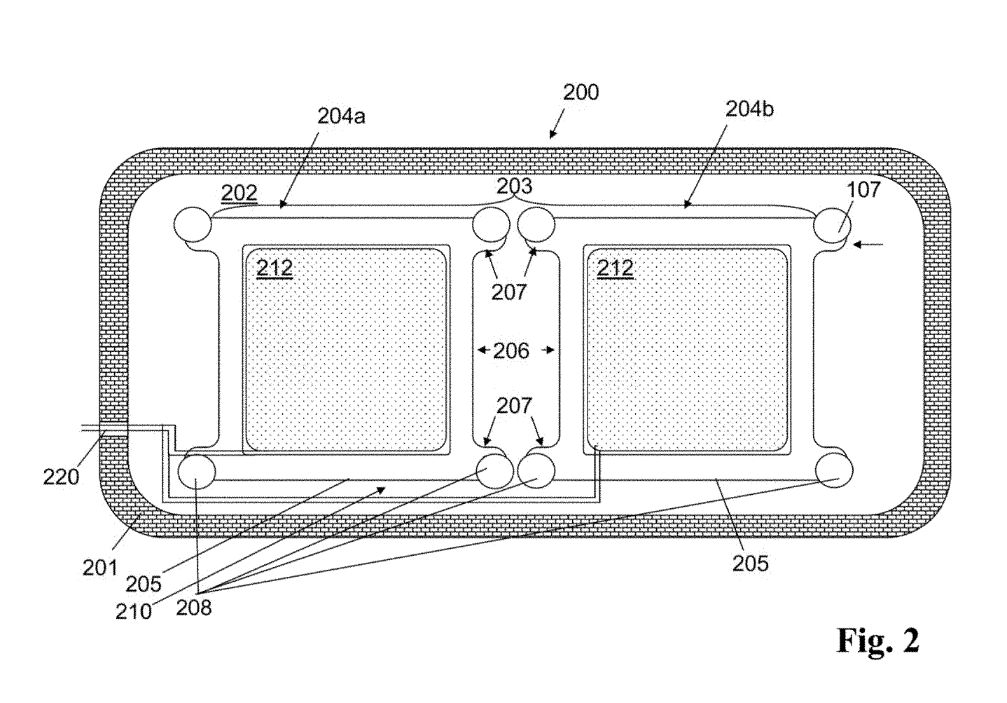

FIG. 2 is a sectional depiction of an apparatus according to the invention for irradiating semiconductor wafers and is labeled overall with the reference number 200. The irradiation apparatus 200 has a housing 201 that encloses a process chamber 202. Arranged in the process chamber 202 is a carrier 203 having two receiving frames 204a, 204b. A single current feedthrough 220 that is conducted through the housing 201 and via which the receiving frames 204a, 204b are attached to a voltage source (not shown) is provided for electrically contacting the receiving frames 204a, 204b.

When the same reference numbers are used in FIG. 2 than were used in FIG. 1, they apply to identical or equivalent components of the carrier as they were described in the foregoing FIG. 1.

The carrier 203 is distinguished from the carrier 100 known from FIG. 1 in that it is embodied in multiple pieces. Substrate support elements 205 that are inserted into cylindrical transverse rods 208 via projections 207 disposed on the transverse sides 206 are provided for receiving the semiconductor wafers. The transverse rods 208 are produced from silica glass having a purity of 99.99%. No additional component has been added to the silica glass of the transverse rods 208.

The transverse rods 208 are provided with slots (not shown) into which one of the projections 207 of a support element may be inserted. The slot depth is 7 mm, the slot width is 4 mm, and the slot interval is 15 mm. The transverse rods 208 have a circular radial cross-section, and the diameter of the transverse rods 208 is 20 mm.

The substrate support elements 205 inserted into the transverse rods 208 have a length of 200 mm (corresponding to the longitudinal side 210 including the projections 207 with a projection length of 30 mm) and a width of 150 mm (corresponding to the transverse side 206). The carrier 203 comprises 40 substrate support elements 205 in 20 levels arranged above one another, wherein two substrate support elements 205 are arranged adjacent to one another in each level.

The substrate support elements 205 are embodied identically. The top side of each of the substrate support elements has a support surface 212 for receiving a semiconductor. The support surface 212 has a width of 101 mm, a length of 101 mm, and a substrate support element height of 2 mm. The substrate support elements 205 are produced from a laminated glass. The laminated glass comprises two elements, specifically a first composite element that forms the support surface 212 and a second composite element that surrounds the support surface 212. The first composite element comprises silica glass having a purity of 99.99%. The second composite element comprises a composite material that is based on a matrix of silica glass and to which 3% elementary silicon by weight has been added as an additional component. A platinum coating that generates heat when current flows through it is added to the bottom of the support surface 212.

Since only the support surface 212 is produced from the second composite element, that is, from the composite material, only the region of the support surface 212 can emit thermal radiation directly. Certainly the other regions of the substrate support element can emit thermal radiation, for instance some radiation that was coupled into the substrate support element. However, as a rule such radiation portions are negligible compared to the total radiant power of the substrate support element. In this context, it has proved advantageous when the substrate support element has a decoupling zone, for example in the form of a roughened surface, in the region of the transition from the first composite element to the second composite element. A roughened surface acts as a diffusor and is associated with a non-directed and therefore uniform radiation emission. An alternative means for reducing the radiant power within the substrate support element is doping the first composite component with a thermal radiation-absorbing doping agent.

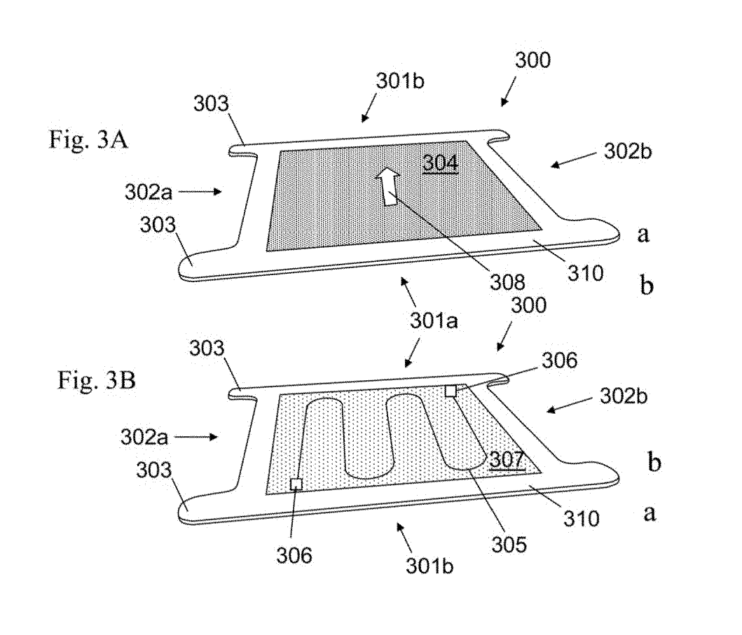

FIGS. 3A and 3B depict two views (a, b) of a substrate support element 300 of the invention.

FIG. 3A provides a perspective elevation of the top side (a) of the substrate support element 300; FIG. 3B depicts the bottom side (b) of the substrate support element 300.

The substrate support element 300 is produced from two materials, specifically, it is made of silica glass in the region 310 surrounding the support surface 304 and it is made of a composite material in the region of the support surface 304. The composite material comprises a matrix made of silica glass. The matrix appears visually translucent to transparent. When viewed under the microscope, it has no open pores and any closed pores have maximum dimensions of on average less than 10 μm. A phase made of elementary silicon in the shape of non-spherical regions is evenly distributed in this matrix. The proportion by weight of the phase made of elementary silicon is 5%. The maximum dimensions of the Si phase regions are on average (median value) in the range of about 1 μm to 10 μm. The composite material is gas-tight; it has a density of 2.19 g/cm³ and is stable in air up to a temperature of about 1200° C.

The intercalated Si phase contributes overall to the opacity of the composite material, on the one hand, and has effects on the optical and thermal properties of the composite material. At high temperatures the composite material exhibits high absorption of thermal radiation and high emittance.

The emissivity of the composite material is measured at room temperature using an integrating sphere (also known as Ulbricht sphere). The Ulbricht sphere permits measurement of the directional hemispherical spectral reflectance R_{gh} and of the directional hemispherical spectral transmittance T_{gh}, from which the normal spectral emissivity is calculated. Using the aforesaid “Black-Body Boundary Conditions” (BBC) measurement principle, the emissivity is measured at an elevated temperature in the wavelength range of 2 to 18 μm by an FTIR spectrometer (Bruker IFS 66v Fourier Transform Infrarot (FTIR)) to which a BBC sample chamber is coupled via an additional optical system. This sample chamber, in the half-spaces in front of and behind the sample mount, has temperature-controllable black-body environments and a beam exit opening with detector. The sample is heated to a predetermined temperature in a separate oven, and for the measurement it is moved into the beam path of the sample chamber with the black body environments set to the predetermined temperature. The intensity captured by the detector is composed of an emission component, a reflection component and a transmission component that is, of intensity emitted by the sample itself, intensity impinging on the sample from the front half-space and reflected by the sample, and intensity which impinges on the sample from the rear half-space and is transmitted by the sample. Three measurements must be carried out in order to determine the individual parameters of emissivity, reflectance, and transmittance.

The emissivity measured on the composite material in the wavelength range from 2 μm to about 4 μm depends on the temperature. The higher the temperature, the higher the emission. At 600° C., the normal emittance in the wavelength range of 2 μm to 4 μm is greater than 0.6. At 1000° C., the normal emittance in the entire wavelength range between 2 μm and 8 μm is greater than 0.75.

The substrate support element 300 has two longitudinal sides 301a, 301b and two transverse sides 302a, 302b. Disposed on each of the transverse sides 302a, 302b are two projections 303 with which the substrate support element 300 may be attached to the transverse rods of a holding frame (not shown).

The substrate support element 300 has a length of 300 mm (corresponding to the longitudinal sides 301a and 301b including each projection 303 having a projection length of 30 mm) and a width of 200 mm (corresponding to the transverse side 302a, 302b). The thickness of the substrate support element 300 is 4 mm.

A support surface 304 in the shape of a rectangular depression is provided for a semiconductor on the top (a) of the substrate support element 300. The support surface 304 has a rectangular shape and has a length of 121 mm and a width of 121 mm. The support surface 304 acts both as a support surface for a substrate and as a radiating surface for thermal radiation. The direction of radiation is indicated by the directional arrow 308.

A conductor path 305 that is produced from a platinum resistance paste is applied to the top surface of the bottom side (b). The conductor path 305 has a meandering course. Contacts 306 for supplying electrical energy are welded to each end of the conductor path 305. The conductor path 305 runs within a surface area 307 that corresponds to the support surface 304. The distance between adjacent conductor path segments is 2 mm. The conductor path 305 has a cross-sectional area of at least 0.02 mm² with a width of 1 mm and a thickness of 20 μm. Because of the thin thickness, the material portion of the expensive conductor path material is low compared to its efficiency. The conductor path 305 has direct contact with the bottom side of the substrate support element 300, so that the greatest possible amount of heat is transferred into the substrate support element 300.

Both the support surface 307 and the conductor path 305 are covered by a reflector layer 309 made of opaque silica glass. The reflector layer 309 has a mean layer thickness of 1.7 mm. It is characterized by a high density of about 2.15 g/cm³. In addition, it is thermally resistant up to temperatures higher than 1100° C. The reflector layer 309 completely covers the conductor 305 and thus protects it from chemical and mechanical influences from the environment. Moreover, it reflects radiation emitted by the substrate support element in the direction of the bottom side and reflects said radiation back towards any substrate that has been placed onto the support surface 304.

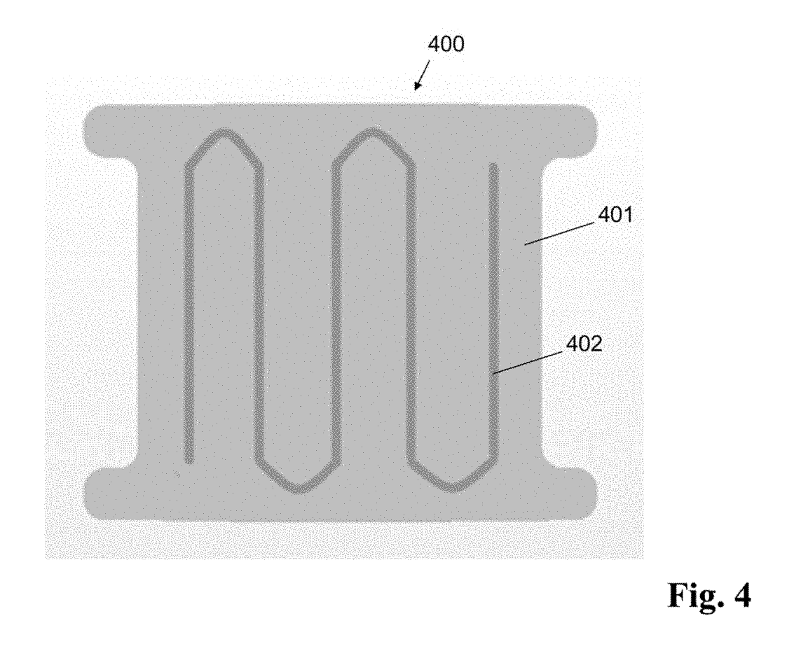

FIG. 4 is a top view of the bottom side 401 of an alternative embodiment of a substrate support element 400.

The substrate support element 400 is produced completely from a composite material, the matrix component of which is silica glass, wherein a phase made of elementary silicon is added to the silica glass at a concentration of 3%.

A conductor path 402 made of a silver paste is printed onto the bottom side 401 and fired. The conductor path 402 has a meandering course in which the curved areas are sharply tapered. This has the advantage that, in contrast to a round curve path, the edge regions of the substrate support element have a lower covering density of the conductor path. This ensures that the edge regions are not heated excessively during operation compared to the center region of the substrate support element 400. The shape of the conductor path thus contributes to the most uniform possible radiation of any substrate positioned on the top. Moreover, no reflector has been applied to the bottom side 401, in particular to the conductor 402, so that radiation emitted in the region of the bottom side 401 is available for irradiating an adjacent substrate disposed there below.

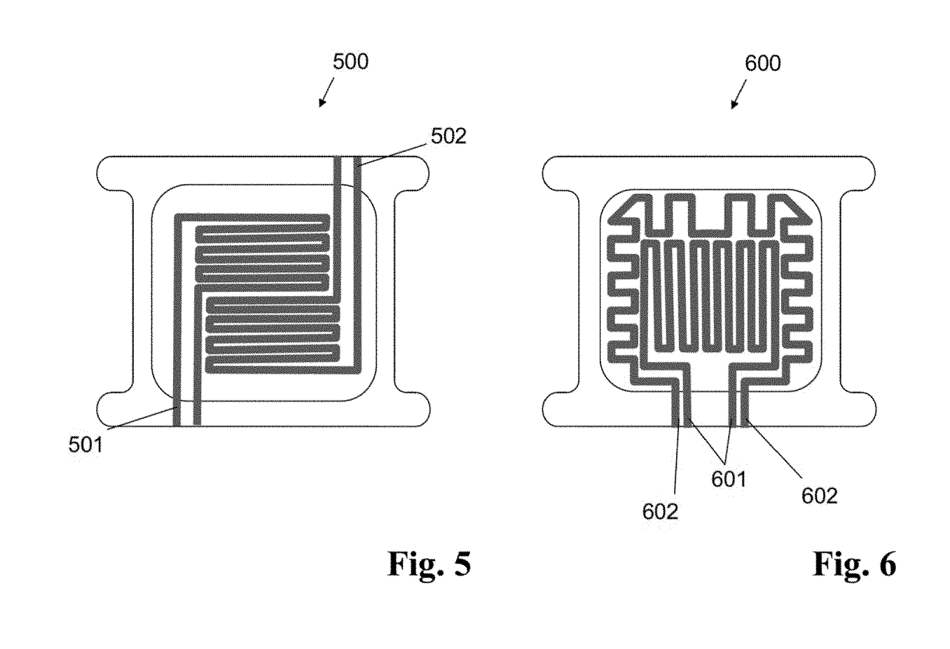

FIG. 5 is a top view of the bottom of an inventive substrate support element having the overall reference number 500. Applied to the bottom side and corresponding to the support surface are two conductor paths 501, 502 made of platinum, and an electrical voltage may be applied to each individually. Since the conductor paths 501, 502 are individually electrically controllable, that is, they may be operated with different operating voltages or operating currents, a desired temperature distribution on the substrate to be heated may be set simply and rapidly by appropriately selecting the operating voltages or operating currents.

FIG. 6 is a top view of the bottom side of a fourth embodiment of a substrate support element 600 of the invention. The substrate support element 600 comprises two conductor paths 601, 602, each of which is individually electrically controllable.

It has been found that during thermal substrate treatment the edge regions of the substrate are frequently heated more intensely than the center region thereof. The most uniform possible temperature distribution is attained on the substrate to be heated in that the conductor paths that may be operated independently from one another with different operating currents or operating voltages are allocated to the edge region and to the center region. In FIG. 6, the conductor path 602 is allocated to the substrate edge region and conductor path 601 is allocated to the substrate center region. It is possible to attain uniform irradiation of the substrate by varying the operating currents or operating voltages applied to the conductor paths 601, 602.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. An apparatus (200) for thermal treatment of a substrate, wherein the apparatus has a heating device and a carrier (100; 203) provided with a support surface (108; 212; 304) for carrying the substrate, wherein at least a part of the carrier (100; 203) comprises a composite material comprising an amorphous matrix component and an additional component comprising a semiconductor material, wherein a conductor path (305; 402; 501; 502; 601; 602) that is a part of the heating device and comprising an electrically conducting resistance material that generates heat when current passes through it is applied to the surface of the carrier (100; 203).

2. The apparatus (200) according to claim 1, further comprising a process chamber (202) in which the carrier (100; 203) is located, wherein the process chamber (202) comprises a process chamber wall with a current feedthrough through which a first electrical potential and a second electrical potential is conducted into the process chamber (202) for electrically contacting the conductor path (305; 402; 501; 502; 601; 602).

3. A carrier (100; 203) for thermal treatment of a substrate, comprising at least one support surface (108; 212; 304) for a substrate, wherein at least a part of the carrier (100; 203) comprises a composite material comprising an amorphous matrix component and an additional component comprising a semiconductor material, and wherein a conductor path (305; 402; 501; 502; 601; 602) comprising an electrically conducting resistance material that generates heat when current flows through it is applied to a surface of the composite material.

4. The carrier (100; 203) according to claim 3, wherein the carrier comprises the composite material in the region of the support surface (108; 212; 304).

5. The carrier (100; 203) according to claim 3, wherein the amorphous matrix component is silica glass and wherein the semiconductor material is present in elementary form, wherein a proportion by weight of the semiconductor material is in a range between 0.1% to 5%.

6. The carrier (100; 203) according to claim 3, wherein the conductor path (305; 402; 501; 502; 601; 602) comprises platinum, high heat resistant steel, tantalum, a ferritic FeCrAl alloy, an austenitic CrFeNi alloy, or a molybdenum-base alloy, and has a cross-sectional area in the range of from 0.01 mm² to 2.5 mm².

7. The carrier (100; 203) according to claim 3, wherein the carrier comprises at least one support element (205; 300; 400; 500; 600) having at least one support surface (108; 212; 304) and a top side and a bottom side (401), wherein the support surface (108; 212; 304) is allocated to the top side and the conductor path (305; 402; 501; 502; 601; 602) is allocated to the bottom side (401).

8. The carrier (100; 203) according to claim 3, wherein a plurality of conductor paths (305; 402; 501; 502; 601; 602) are provided, wherein each of the conductor paths is individually electrically controllable.

9. The carrier (100; 203) according to claim 3, wherein the carrier is designed for receiving a wafer-shaped substrate made of semiconductor material in a horizontal orientation.

10. A substrate support element (205; 300; 400; 500; 600) for a carrier (100; 203) for thermal treatment of a substrate, wherein the carrier has a support surface (108; 212, 304) for carrying the substrate, wherein the support element (205; 300; 400; 500; 600) comprises a composite material comprising an amorphous matrix component and an additional component comprising a semiconductor material, wherein a conductor path (305; 402; 501; 502; 601; 602); made of an electrically conducting resistance material that generates heat when current passes through it is applied to a surface of the composite material.
